(19) United States
(12) Patent Application Publication
(10) Pub. No.: US 2003/0115532 A1
(43) Pub. Date: Jun. 19, 2003

(54) Turbo code encoder and code rate decreasing method thereof

(76) Inventors: Jung-Im Kim, Daejeon (KR); Seung Chan Bang, Daejeon (KR)

Correspondence Address: JACOBSON HOLMAN PLLC, 400 SEVENTH STREET N.W., SUITE 600, WASHINGTON, DC, 20004, US

(21) Appl. No.: 10/029,944

(22) Filed: Dec. 31, 2001

(30) Foreign Application Priority Data
Dec. 14, 2001 (KR) 2001-79318

(51) Int. Cl. H03M 13/00

(52) U.S. Cl. 714/758

(57) ABSTRACT

Disclosed are a turbo code encoder and a code rate decreasing method thereof. The turbo code encoder includes: a first convolutional encoder for receiving a bit to be encoded, and generating a systematic bit and a first parity bit; an interleaver for receiving the bit to be encoded, in parallel with the first convolutional encoder, and interleaving the received bit; and a second convolutional encoder for receiving the interleaved bit from the interleaver and generating a second parity bit. The code rate decreasing method of the turbo code encoder having a code rate of 1/3 includes repeatedly outputting predefined bits among the bits output from the first and second convolutional encoders.

### BACKGROUND OF THE INVENTION

(a) Field of the Invention

The present invention relates to a turbo code encoder. More specifically, the present invention relates to a turbo code encoder and a code rate decreasing method thereof in which the bits of the turbo code encoder are repeated to reduce the code rate of the encoder and thereby acquire a coding gain with a minimum of complexity.

(b) Description of the Related Art

In general, a communication system performs channel coding of information signals and uses forward error correction codes for restoration of the coded signals at the receiver in order to avoid distortion of the information signals caused by the channel environment. The forward error correction codes are used to reduce the probability of signal distortion with a parity bit in restoration of the signals distorted in the channel environment by inserting the parity bit into the signals to be transmitted.

The forward error correction code comprises an encoder and a decoder. The former is located at the transmitter to generate the parity bit of the signal to be transmitted, and the latter is located at the receiver to restore the signal, to be sent from the transmitter, using the parity bit.

An error correction method that sends the input information signals of the encoder together with the parity bit is called a “systematic” method, and an error correction method that sends the parity bit alone without the information signals is called a “non-systematic” method.

The code rate is the ratio of the information signal to the parity bit. As the parity bit increases, the code rate is reduced to decrease the probability of signal distortion and thereby enhance the performance.

The performance of the forward error correction codes is normally dependent on the minimum distance or free distance between the codes and the distribution of the code word. In this respect, the conventional turbo code encoder having a code rate of 1/4 adds a second polynomial to the turbo code encoder having a code rate of 1/3 to reduce the code rate from 1/3 to 1/4. Namely, the coding method of the turbo code encoder having a code rate of 1/4 increases the distance between the codes to enhance the coding gain.

Now, a detailed description will be given to the error correction related to the present invention and the prior art by way of the standard method of the IMT-2000 system. Turbo codes are used as the standard technology of the forward error correction codes in the IMT-2000 system.

FIG. 1 is a schematic of a turbo code encoder having a code rate of 1/3 used in the IMT-2000 system. Referring to FIG. 1, the turbo code encoder comprises first and second recursive systematic convolutional encoders connected in parallel with each other.

FIG. 1 shows the relationship between input and output data of the turbo codes. The recursive systematic convolutional encoders encode the data according to the characteristic of a transfer function G(D).

From an input X(t) having N bits of X₁, X₂, . . . , and X_{N}, the outputs are X(t), Y(t), and Z(t), where X(t) represents a systematic bit and Y(t) and Z(t) represent parity bits. Y(t) has N bits of Y₁, Y₂, . . . , and Y_{N}, and Z(t) has N bits of Z₁, Z₂, . . . , and Z_{N}.

Namely, the first recursive systematic convolutional encoder 120 outputs both the systematic bit X(t) and the parity bit Y(t). The second recursive systematic convolutional encoder 130 receives the systematic bit X(t) interleaved according to the regulation of a turbo interleaver 110 and encodes it to the parity bit Z(t).

Unlike the first convolutional encoder 120, the second convolutional encoder 130 outputs only the parity bit Z(t) other than the systematic bit. Here, the code rate of 1/3 refers to the ratio of the input X(t) to the outputs X(t), Y(t) and Z(t).

As seen from FIG. 1, the conventional turbo code encoder having a code rate of 1/3 outputs the final data in the order of X₁, Y₁, Z₁, X₂, Y₂, Z₂, . . . , X_{N}, Y_{N}, and Z_{N}.

In the synchronous IMT-2000 system, the turbo code encoder having a code rate of 1/4 adds a second polynomial n2(D) to a recursive polynomial d(D) and a polynomial n1(D) that are used for a code rate of 1/3.

FIG. 2 is a schematic of a conventional turbo code encoder having a code rate of 1/4.

The turbo code encoder 200 having a code rate of 1/4 encodes X(t), Y₂(t), and Z₁(t) of the polynomial used in the turbo code encoder having a code rate of 1/4 into parity bits Y₂(t) (having N bits of Y₂₁, Y₂₂, Y₂₃, . . . , and Y₂ₙ) and Z₂(t) (having N bits of Z₂₁, Z₂₂, Z₂₃, . . . , and Z₂ₙ) of the additionally inserted second polynomial n2(D). Y₂(t) is output data from a first recursive systematic convolutional encoder 220 and Z₂(t) is from a second recursive systematic convolutional encoder 230.

As seen from FIG. 2, the conventional turbo code encoder having a code rate of 1/4 outputs the final data in the order of X₁, Y₁₁, Z₁₁, Z₂₁, Z₂, Y₁₂, Y₂₂, Z₁₂, X₃, Y₁₃, Z₁₃, Z₂₃, . . . , X_{N}, Y_{1N}, Y_{2N}, and Z_{1N}. Namely, Y₂₁, Y₂₃, Y₂₅, Y₂₇, . . . , and Y_{2N-1} output from the first recursive systematic convolutional encoder 220 and Z₂₂, Z₂₄, to Z₂₆, Z₂₈, . . . , and Z_{2N} output from the second recursive systematic convolutional encoder 230 are punctured and omitted in transmission.

Puncturing is performed to satisfy the code rate of 1/4. Compared to the coding method using a code rate of 1/3, the conventional coding method using a code rate of 1/4 increases the number of memories in the encoder due to the increased parity bits Y₂(t) and Z₂(t) as well as the number of memories for storing the parity bits and the number of operations at the receiver.

Because the conventional turbo code encoder having a code rate of 1/4 adds a second polynomial to the turbo code encoder having a code rate of 1/3 to generate more parity bits and thereby reduce the code rate, the storage of the additional parity bits and the increased number of operations increase the complexity of the system.

### SUMMARY OF THE INVENTION

It is an object of the present invention to solve the problem with the prior art and to provide a turbo code encoder and a code rate decreasing method thereof in which a coding gain can be acquired with a minimum of complexity by repeating the bit of the encoder to reduce the code rate instead of by adding a second polynomial to the systematic error correction codes to generate an additional parity bit.

The present invention provides a novel coding method of turbo codes having a code rate of 1/4 that repeats the systematic bit of turbo codes having a code rate of 1/3. Compared to the conventional method, the present invention reduces the complexity of the system while maintaining the performance of the conventional method or slightly enhancing the performance depending on the structure of the decoder at the receiver.

In one aspect of the present invention, there is provided a turbo code encoder that includes: a first convolutional encoder for receiving a bit to be encoded, and generating a systematic bit and a first parity bit; an interleaver for receiving the bit to be encoded, in parallel with the first convolutional encoder, and interleaving the received bit; a second convolutional encoder for receiving the interleaved bit from the interleaver and generating a second parity bit; and a repeater for repeatedly outputting predefined bits among the bits output from the first and second convolution encoders.

In another aspect of the present invention, there is provided a code rate decreasing method of a turbo code encoder that includes: (a) receiving a bit to be encoded, and generating a systematic bit and a first parity bit; (b) receiving the bit to be encoded, in parallel with the first convolutional encoder, and interleaving the received bit; (c) receiving the interleaved bit from the interleaver and generating a second parity bit; and (d) repeatedly outputting predefined bits among the bits output from the steps (a) and (c).

### BRIEF DESCRIPTION OF THE DRAWINGS

The accompanying drawings, which are incorporated in and constitute a part of the specification, illustrate an embodiment of the invention, and, together with the description, serve to explain the principles of the invention:

FIG. 1 is a schematic of a turbo code encoder having a code rate of 1/3 used in an IMT-2000 system;

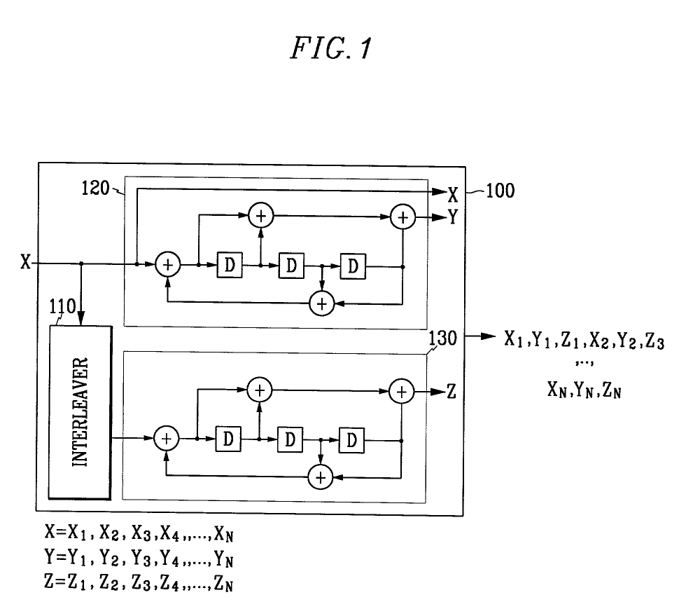

FIG. 2 is a schematic of a turbo code encoder having a code rate of 1/4 used in an IMT-2000 system;

FIG. 3 is a schematic of a turbo code encoder in accordance with an embodiment of the present invention; and

FIG. 4 shows the simulation results of the prior art and the present invention.

### DETAILED DESCRIPTION OF THE PREFERRED EMBODIMENTS

In the following detailed description, only the preferred embodiment of the invention has been shown and described, simply by way of illustration of the best mode contemplated by the inventor(s) of carrying out the invention. As will be realized, the invention is capable of modification in various obvious respects, all without departing from the invention. Accordingly, the drawings and description are to be regarded as illustrative in nature, and not restrictive.

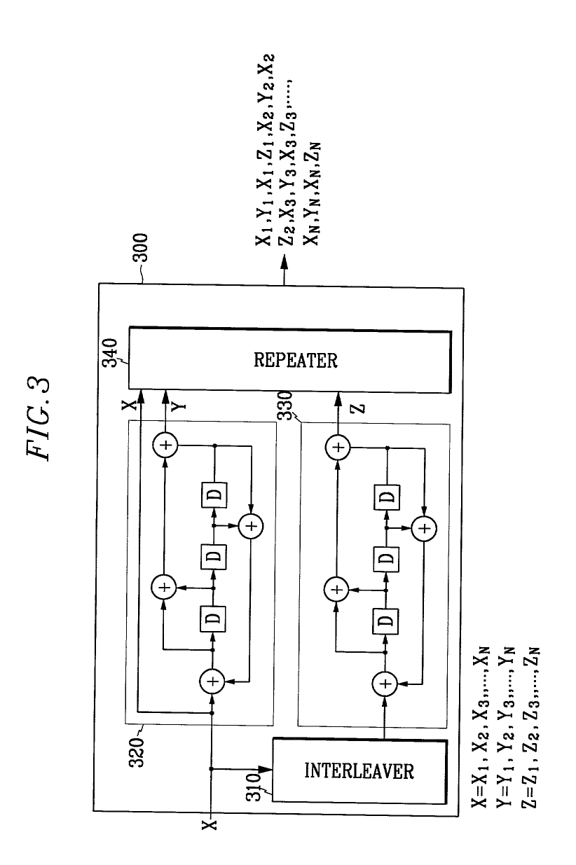

FIG. 3 is a schematic of a turbo code encoder in accordance with an embodiment of the present invention.

Referring to FIG. 3, the turbo code encoder 300 according to an embodiment of the present invention comprises an interleaver 310, a first recursive systematic convolutional encoder 320, a second recursive systematic convolutional encoder 330, and a repeater 340. The first recursive systematic convolutional encoder 320 receives a bit to be encoded, and generates a systematic bit and a first parity bit. The interleaver 310 receives the bit to be encoded, in parallel with the first convolutional encoder 320, and interleaves the received bit. The second recursive systematic convolutional encoder 330 receives the interleaved bit from the interleaver 310, generates a second parity bit and outputs it. The repeater 340 repeatedly outputs predefined bits among the bits output from the first and second recursive systematic convolutional encoders 320 and 330.

Now, a description will be given to an operation of the turbo code encoder in accordance with an embodiment of the present invention.

First, N bits (X) to be encoded are fed into the first recursive systematic convolutional encoder 320. The first recursive systematic convolutional encoder 320 generates N systematic bits and N parity bits from the input bits and outputs them to the repeater 340.

The interleaver 310 interleaves the N bits (X) to be encoded.

Subsequently, the second recursive systematic convolutional encoder 330 generates N parity bits from the N interleaved bits and outputs them to the repeater 340. As a result, the repeater 340 receives 3N bits, i.e., 2N parity bits plus N systematic bits.

Upon receiving 3N bits, the repeater 340 repeats N systematic bits and to outputs 4N bits to realize a code rate of 1/4.

The output signals are in the order of X₁, Y₁, X₁, Z₁, X₂, Y₂, X₂, Z₂, . . . , X_{N}, Y_{N}, X_{N}, and Z_{N}, as shown in FIG. 3.

This method associates the repeated systematic bits upon receipt of the bits in the decoder of the receiver, using 3N memories.

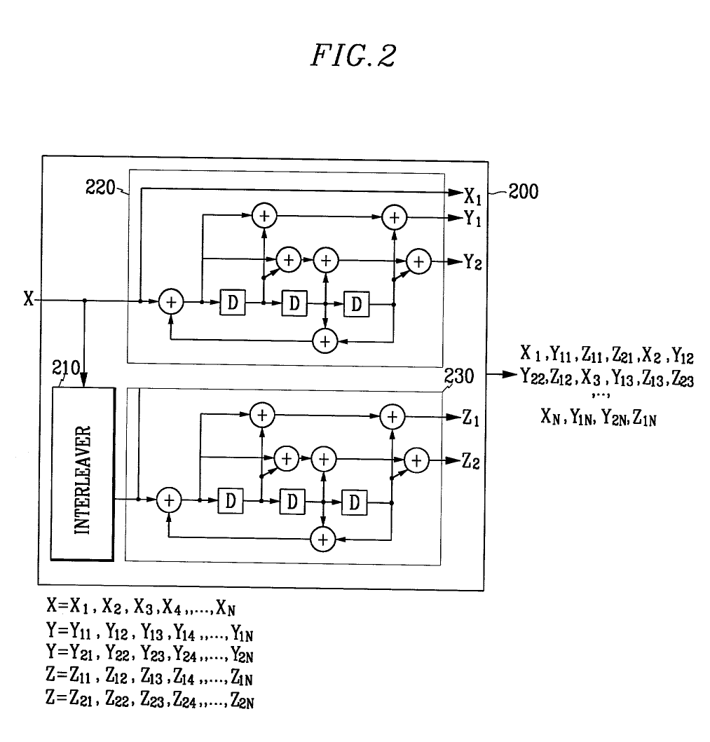

In the conventional method as shown in FIG. 2, however, at least 4N memories are required in the decoder of the receiver and additional memories are needed depending on the processing method of the punctured bits.

As described in the embodiment of the present invention for sending turbo codes having a code rate of 1/4, the decoder of the receiver decodes data with the same number of memories as used for sending turbo codes having a code rate of 1/3. Namely, the number of memories necessary for calculation of prior and posterior probabilities is the same irrespective of whether the code rate is 1/3 or 1/4.

Contrarily, the conventional method increases the number of operations for processing parity bits generated by the second polynomial of the encoder and requires more memories to store the parity bits in order to reduce the code rate from 1/3 to 1/4.

A comparison of performance between the present invention algorithm repeating the systematic bit and the conventional algorithm increasing the distance between the codes can be given in the following two points of view.

First, in the aspect of the minimum distance, the present invention method is inferior in performance to the conventional turbo coding method in which the code rate is 1/4. But, the performance difference related to the minimum distance is insignificant, because the conventional method punctures the data every one of five bits in order to keep the transmit speed of the data and thereby reduces the minimum distance by the data puncturing.

Secondly, use is made of a MAP algorithm for turbo codes in the decoder. The MAP algorithm repeatedly calculates a prior probability to increase the reliability to a posterior probability and hence the coding performance gain. The prior and posterior probabilities are functions of the systematic bit, and the intermediate equation for calculating the posterior probability is a product of the prior probability by the systematic bit. Namely, the accuracy of the systematic bit guarantees the accurate calculation of the posterior probability.

The present invention repeats the systematic bit transmission to increase the accuracy of the prior and posterior probabilities and thereby enhance the performance of the turbo decoder. In the two points of view, a comparison of performance between the present invention method and the conventional method will be described with reference to the results of simulations.

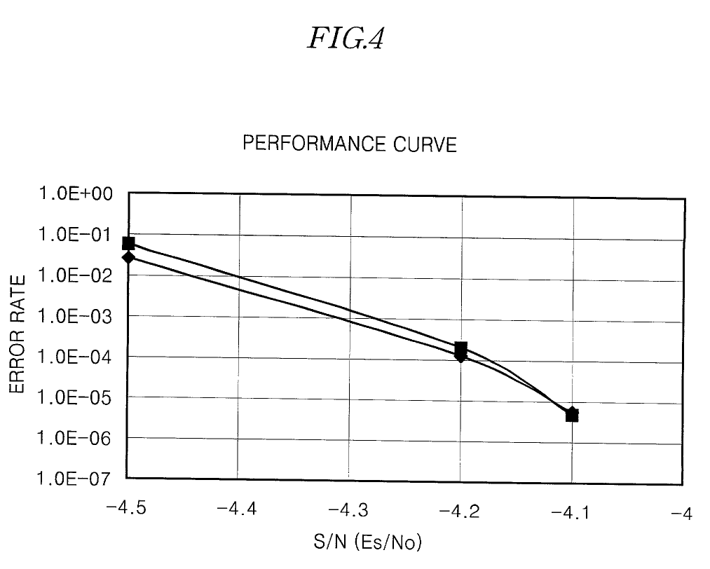

Referring to FIG. 4, the performance curve of the present invention method (the upper curve) is similar to that of the conventional method (the lower curve) in that the error rate decreases with an increase in the signal-to-noise ratio, i.e., as the channel environment is more favorable. Especially, the error rate is 10⁻⁵ to 10⁻⁶ at the signal-to-noise ratio (Es/No) of −4.1.

As seen from the results of the simulations, there is almost no difference in the performance between the present invention method and the conventional method. That is, the present invention increases the accuracy of the systematic bit but the conventional method increases the minimum distance between the codes, and in both cases the performance is enhanced.

In the conventional channel coding method, the complexity increases as the code rate is reduced. Contrarily, the present invention method retransmits the bit of the encoder to reduce the code rate instead of using a second polynomial in the encoder and thereby enhances the performance without an increase in the complexity.

The present invention method is applicable to the systematic codes as well as the turbo codes. Although it has been described in the preferred embodiment of the present invention that the systematic bit is repeated for a code rate of 1/4, the presently considered to be the most practical and preferred embodiment, it is to be understood that the invention is not limited to the disclosed embodiments, but, on the contrary, is intended to cover various modifications and equivalent arrangements included within the spirit and scope of the appended claims.

As described above, the code rate decreasing method for the forward error correction codes such as turbo codes according to the present invention repeats the bits of the encoders to reduce the code rate and thereby enhance the performance without a large increase in the complexity, while the conventional channel coding method increases the complexity as the code rate is reduced.

What is claimed is:

1. A turbo code encoder comprising:
a first convolutional encoder for receiving bits to be encoded, generating a systematic bit and a first parity bit, and outputting them;
an interleaver for receiving the bits to be encoded, in parallel with the first convolutional encoder, and interleaving the received bits;
a second convolutional encoder for receiving the interleaved bits from the interleaver and generating a second parity bit; and
a repeater for repeatedly outputting predefined bits among the bits output from the first and second convolution encoders.

2. The turbo code encoder as claimed in claim 1, wherein the repeater repeatedly outputs the systematic bit.

3. The turbo code encoder as claimed in claim 2, wherein the repeater outputs signals in the order of the systematic bit, the first parity bit, the systematic bit, and the second parity bit.

4. The turbo code encoder as claimed in claim 1, wherein the repeater repeatedly outputs the first parity bit.

5. The turbo code encoder as claimed in claim 1, wherein the repeater repeatedly outputs the second parity bit.

6. A code rate decreasing method of a turbo code encoder, comprising:
(a) receiving bits to be encoded, and generating a systematic bit and a first parity bit;
(b) receiving the bits to be encoded, and interleaving the received bits;
(c) receiving the interleaved bits and generating a second parity bit; and
(d) repeatedly outputting predefined bits among the bits output from the steps (a) and (c).

7. The code rate decreasing method as claimed in claim 6, wherein the step (d) comprises repeating the systematic bit and outputting data in the order of the systematic bit, the first parity bit, the systematic bit, and the second parity bit.

8. The code rate decreasing method as claimed in claim 6, wherein the step (d) comprises repeatedly outputting the first parity bit among the bits output from the steps (a) and (c).

9. The code rate decreasing method as claimed in claim 6, wherein the step (d) comprises repeatedly outputting the systematic bit and the first parity bit and reducing the code rate through puncturing, when the code rate is less than 1/4.
